(19) United States
(12) Patent Application Publication
(10) Pub. No.: US 2024/0298454 A1
(43) Pub. Date: Sep. 5, 2024

(54) MULTICHANNEL MEMORY WITH SERDES

(71) Applicant: ADEIA SEMICONDUCTOR BONDING TECHNOLOGIES INC., San Jose, CA (US)

(72) Inventor: Belgacem HABA, Saratoga, CA (US)

(21) Appl. No.: 18/590,388

(22) Filed: Feb. 28, 2024

Related U.S. Application Data
(60) Provisional application No. 63/487,824, filed on Mar. 1, 2023.

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0652; H01L 25/18; H01L 25/50; H01L 2224/08145; H01L 2224/80895; H01L 2224/80896; H01L 2225/06562; H01L 2225/06582; H01L 2924/1431; H01L 2924/1436

(57) ABSTRACT

A bonded structure is disclosed. The bonded structure can include a carrier. The bonded structure can include a first memory unit disposed on the carrier having a first memory channel and a first plurality of memory dies directly hybrid bonded to one another. The bonded structure can also include a second memory unit having a second memory channel different from the first memory channel and a second plurality of memory dies directly hybrid bonded to one another. The second memory unit can be stacked on top of the first memory unit. The bonded structure can include a serializer-deserializer disposed in or on the carrier and electrically connected to the first and second memory channels of the first and second memory units. The serializer-deserializer can have an external channel configured to electrically connect the bonded structure to a processor.

### RELATED APPLICATIONS

This application claims the priority benefit of U.S. Provisional Patent Application No. 63/487,824 filed on Mar. 1, 2023, entitled “MULTICHANNEL MEMORY WITH SERDES,” which is incorporated by reference herein in its entirety.

### BACKGROUND

### Field

This disclosure relates to semiconductor device structures and methods. Some embodiments are directed to multichannel memory.

### Description of the Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Multiple semiconductor elements can be stacked in various applications such as high bandwidth memory.

### SUMMARY

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these implementations are intended to be within the scope of the invention herein disclosed. These and other implementations will become readily apparent to those skilled in the art from the following detailed description of the preferred implementations having reference to the attached figures, the invention not being limited to any particular preferred implementations disclosed.

In one implementation a bonded structure can include: a carrier; a first memory unit disposed on the carrier, the first memory unit including a first memory channel, the first memory unit including a first plurality of memory dies directly hybrid bonded to one another; a second memory unit including a second memory channel different from the first memory channel, the second memory unit including a second plurality of memory dies directly hybrid bonded to one another, the second memory unit stacked on top of the first memory unit; and a serializer-deserializer disposed in or on the carrier and electrically connected to the first and second memory channels of the first and second memory units, the serializer-deserializer having an external channel configured to electrically connect the bonded structure to a processor.

In some implementations, the carrier includes a logic die. In some implementation, the bonded structure includes a logic die, wherein the carrier includes an interposer, and wherein the logic die is disposed between the first memory unit and the interposer. In some implementations, the bonded structure includes an encapsulant and a logic die; wherein the carrier includes a redistribution layer; wherein the logic die is disposed between the first memory unit and the redistribution layer; wherein the first memory unit, the second memory unit, the logic die; and the serializer-deserializer are partially enclosed in the encapsulant. In some implementations, the bonded structure includes a logic die, wherein the carrier includes a printed circuit board, wherein the logic die is disposed between the first memory unit and the printed circuit board.

In some implementations, the first memory unit is directly hybrid bonded to the second memory unit. In some implementations, the first memory unit is directly hybrid bonded to the carrier. In some implementations, the serializer-deserializer is directly hybrid bonded to the carrier.

In another implementation, a structure can include: a first memory unit having a top surface and a bottom surface, the first memory unit comprising a first plurality of memory dies directly hybrid bonded to one another; a second memory unit having a top surface and a bottom surface, the second memory unit comprising a second plurality of memory dies directly hybrid bonded to one another; a logic die having a top surface and a bottom surface; and a serializer-deserializer having a top surface and a bottom surface, wherein the bottom surface of the second memory unit is disposed on the top surface of the first memory unit, wherein the bottom surface of the first memory unit is disposed on the top surface of the logic die, wherein the bottom surface of the serializer-deserializer is disposed on the top surface of the logic die, wherein the structure has a first number of internal channels electrically connecting the serializer-deserializer, the logic die, the first memory unit, and the second memory unit, wherein the structure has a second number of external channels configured to electrically connect the structure to a processor, wherein the first number is greater than the second number.

In some implementations, the first number of internal channels is two, and wherein the second number of external channels is one. In some implementations, the techniques described herein relate to a structure, wherein the first number of internal channels is four, and wherein the second number of external channels is one. In some implementations, the second memory unit is directly hybrid bonded to the first memory unit.

In some implementations, the first memory unit is directly hybrid bonded to the logic die. In some implementations, the serializer-deserializer is directly hybrid bonded to the logic die. In some implementations, a first internal channel is electrically connected to active circuitry of the first memory unit, wherein a second internal channel is electrically connected to active circuitry of the second memory unit, wherein the second internal channel is not electrically connected to active circuitry of the first memory unit.

In another implementation, a structure can include: a first memory unit having a top surface and a bottom surface, the first memory unit comprising a first plurality of memory dies directly hybrid bonded to one another; a second memory unit having a top surface and a bottom surface, the second memory unit comprising a second plurality of memory dies directly hybrid bonded to one another; a logic die having a top surface and a bottom surface; an interposer having a top surface and a bottom surface; and a serializer-deserializer having a top surface and a bottom surface; wherein the bottom surface of the second memory unit is disposed on the top surface of the first memory unit; wherein the bottom surface of the first memory unit is disposed on the top surface of the logic die; wherein the bottom surface of the logic die is disposed on the top surface of the interposer; wherein the bottom surface of the serializer-deserializer is disposed on the top surface of the interposer; wherein the structure has a first number of internal channels electrically connecting the serializer-deserializer, the logic die, the first memory unit, and the second memory unit; wherein the structure has a second number of external channels configured to electrically connect the structure to a processor; and wherein the first number is greater than the second number.

In some implementations, the first number of internal channels is two, and wherein the second number of external channels is one. In some implementations, the first number of internal channels is four, and wherein the second number of external channels is one.

In some implementations, the second memory unit is directly hybrid bonded to the first memory unit. In some implementations the first memory unit is directly hybrid bonded to the logic die. In some implementations, the serializer-deserializer is directly hybrid bonded to interposer. In some implementations, the logic die is directly hybrid bonded to the interposer.

In some implementations, a first internal channel is electrically connected to active circuitry of the first memory unit, wherein a second internal channel is electrically connected to active circuitry of the second memory unit, wherein the second internal channel is not electrically connected to active circuitry of the first memory unit.

In another implementation, a structure can include: a first memory unit having a top surface and a bottom surface, the first memory unit comprising a first plurality of memory dies directly hybrid bonded to one another; a second memory unit having a top surface and a bottom surface, the second memory unit comprising a second plurality of memory dies directly hybrid bonded to one another; a logic die having a top surface and a bottom surface; a redistribution layer; a serializer-deserializer having a top surface and a bottom surface; and an encapsulant; wherein the top surface of the second memory unit disposed on the bottom surface of the first memory unit; wherein the top surface of the first memory unit is disposed on the bottom surface of the logic die; wherein the first memory unit, second memory unit, logic die, and serializer-deserializer are at least partially enclosed in the encapsulant; wherein the top surface of the logic die and the top surface of the serializer-deserializer are exposed; wherein the redistribution layer is formed over the top surface of the serializer-deserializer and the top surface of the logic die; wherein the redistribution layer electrically connects the serializer-deserializer and the logic die; wherein the redistribution layer is configured to electrically connect the serializer-deserializer to a processor; wherein the structure has a first number of internal channels electrically connecting the serializer-deserializer, the logic die, the first memory unit, and the second memory unit; and wherein the structure has a second number of external channels configured to electrically connect the structure to a processor, wherein the first number is greater than the second number.

In some implementations, the first number of internal channels is two, and wherein the second number of external channels is one. In some implementations, the first number of internal channels is four, and wherein the second number of external channels is one. In some implementations, the second memory unit is directly hybrid bonded to the first memory unit. In some implementations, the first memory unit is directly hybrid bonded to the logic die.

In some implementations, the redistribution layer is deposited. In some implementations, the redistribution layer is directly hybrid bonding to the logic die and the serializer-deserializer.

In some implementations, a first internal channel is electrically connected to active circuitry of the first memory unit, wherein a second internal channel is electrically connected to active circuitry of the second memory unit, wherein the second internal channel is not electrically connected to active circuitry of the first memory unit.

In another implementation, a structure can include: a first memory unit having a top surface and a bottom surface, the first memory unit comprising a first plurality of memory dies directly hybrid bonded to one another; a second memory unit having a top surface and a bottom surface, the second memory unit comprising a second plurality of memory dies directly hybrid bonded to one another; a logic die having a top surface and a bottom surface; a substrate; and a serializer-deserializer having a top surface and a bottom surface, wherein the bottom surface of the second memory unit is disposed on the top surface of the first memory unit, wherein the bottom surface of the first memory unit is disposed on the top surface of the logic die, wherein the top surface of the logic die is disposed on a bottom surface of the substrate, wherein the serializer-deserializer is embedded in the substrate, wherein the serializer-deserializer is electrically connected to the logic die, wherein the structure has a first number of internal channels electrically connecting the serializer-deserializer, the logic die, the first memory unit, and the second memory unit, wherein the structure has a second number of external channels configured to electrically connect the serializer-deserializer to a processor, wherein the first number is greater than the second number.

In some implementations, the first number of internal channels is two, and wherein the second number of external channels is one. In some implementations, the first number of internal channels is four, and wherein the second number of external channels is one.

In some implementations, the second memory unit is directly hybrid bonded to the first memory unit. In some implementations, the first memory unit is directly hybrid bonded to the logic die.

In some implementations, a first internal channel is electrically connected to active circuitry of the first memory unit, wherein a second internal channel is electrically connected to active circuitry of the second memory unit, wherein the second internal channel is not electrically connected to active circuitry of the first memory unit. In some implementations, the substrate includes a printed circuit board.

In another implementation, a bonded structure can include: a carrier; a first memory unit disposed on the carrier, the first memory unit including a first memory channel and a first plurality of memory dies directly hybrid bonded to one another; a second memory unit including a second memory channel different from the first memory channel and a second plurality of memory dies directly hybrid bonded to one another, the second memory unit stacked on top of the first memory unit; and a serializer-deserializer directly hybrid bonded to the carrier and electrically connected to the first and second memory channels of the first and second memory units, the serializer-deserializer having an external channel configured to electrically connect the bonded structure to a processor.

In some implementations, the bonded structure has a first number of internal channels electrically connecting the serializer-deserializer, the logic die, the first memory unit, and the second memory unit, wherein a second number of external channels is configured to electrically connect the structure to a processor, and wherein the first number is different than the second number.

In some implementations, the carrier includes a logic die. In some implementations, the bonded structure further includes: a logic die; wherein the carrier includes an interposer, and wherein the logic die is disposed between the first memory unit and the interposer. In some implementations, the bonded structure further includes: an encapsulant; and a logic die, wherein the carrier includes a redistribution layer; wherein the logic die is disposed between the first memory unit and the redistribution layer; wherein the first memory unit, the second memory unit, the logic die, and the serializer-deserializer are partially enclosed in the encapsulant. In some implementations, the bonded structure further includes: a logic die; wherein the carrier includes a printed circuit board, wherein the logic die is disposed between the first memory unit and the printed circuit board.

In some implementations, the first memory unit is directly hybrid bonded to the second memory unit. In some implementations, the first memory unit is directly hybrid bonded to the carrier.

In another implementation, a bonded structure can include: a carrier; a first memory unit including a first memory channel and a second memory unit including a second memory channel different from the first memory channel, wherein the second memory unit is stacked on top of the first memory unit, wherein the first memory unit and the second memory unit are disposed on the carrier, wherein the first memory unit comprises a first plurality of memory dies directly hybrid bonded to one another, wherein the second memory unit comprises a second plurality of memory dies directly hybrid bonded to one another; and a serializer-deserializer is disposed on or at least partially embedded in the carrier and electrically connected to the first and second memory channels of the first and second memory units, the serializer-deserializer having an external channel configured to electrically connect the bonded structure to a processor.

In some implementations, the bonded structure has a first number of internal channels electrically connecting the serializer-deserializer, the carrier, the first memory unit, and the second memory unit, wherein a second number of external channels is configured to electrically connect the structure to a processor, and wherein the first number is different than the second number. In some implementations, the serializer-deserializer is directly hybrid bonded to the carrier.

In some implementations, the carrier includes a logic die. In some implementations, the bonded structure further includes: a logic die; wherein the carrier includes an interposer, and wherein the logic die is disposed between the first memory unit and the interposer. In some implementations, the bonded structure further includes: an encapsulant; and a logic die; wherein the carrier includes a redistribution layer; wherein the logic die is disposed between the first memory unit and the redistribution layer; wherein the first memory unit, the second memory unit, the logic die, and the serializer-deserializer are partially enclosed in the encapsulant. In some implementations, the bonded structure further includes: a logic die; wherein the carrier includes a printed circuit board, wherein the logic die is disposed between the first memory unit and the printed circuit board.

In some implementations, the first memory unit is directly hybrid bonded to the second memory unit. In some implementations, the first memory unit is directly hybrid bonded to the carrier.

### BRIEF DESCRIPTION OF THE DRAWINGS

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1 schematically illustrates a prior art implementation of high bandwidth memory.

FIG. 2 schematically illustrates another prior art high bandwidth memory implementation.

FIG. 3 schematically illustrates an example of a multichannel memory module.

FIGS. 4-5D schematically illustrate examples of multichannel memory that utilize a serializer-deserializer according to some embodiments.

FIGS. 6A-6B schematically illustrate a direct bonding process according to some embodiments.

### DETAILED DESCRIPTION

Although several embodiments, examples, and illustrations are disclosed below, it will be understood by those of ordinary skill in the art that the inventions described herein extend beyond the specifically disclosed embodiments, examples, and illustrations and includes other uses of the inventions and obvious modifications and equivalents thereof. Embodiments are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the inventions. In addition, embodiments can comprise several novel features. No single feature is solely responsible for its desirable attributes or is essential to practicing the inventions herein described.

There is significant demand for higher memory bandwidth and higher memory capacity. Providing high speed, high bandwidth connections between memory and processors can be important for some applications. For example, when training an artificial intelligence or machine learning model, performing complex graphical operations, or carrying out other data-intensive tasks, processors such as central processing units (CPUs), graphical processing units (GPUs), field programmable gate arrays (FPGAs), application-specific integrated circuits (ASICs), and so forth can spend a significant amount of time idle while waiting for data, which can negatively impact performance and increase the time it takes to complete computing tasks.

Conventional high bandwidth memory (HBM) implementations use stacked memory close to the processor. For example, memory dies (e.g., dynamic random access memory (DRAM) dies) can be stacked and connected to a memory controller of a processor (e.g., a GPU or CPU) through a carrier (e.g., a silicon interposer). In some embodiments, a controller die can be present in the stack. A typical HBM stack can comprise a plurality of (e.g., four) DRAM dies and a logic layer (e.g., a controller die). In some implementations, memory dies can be stacked directly on a processor and connected to the processor using through-silicon vias.

HBM can offer several advantages as compared to using separate memory that is socketed or soldered to a PCB. For example, power consumption can be lower, form factors can be smaller, and bandwidth can be significantly higher. However, there are several drawbacks and limitations of current HBM implementations. For example, memory dies are typically fabricated separately and contact pads are formed on the memory dies. The dimensions of the contact pads can be, for example, about 25 micrometers and can have a pitch of about 55 micrometers. These large feature sizes can limit the total number of interconnects that can be formed within a given area. Additionally, to achieve high bandwidth and low latency, it can be important to locate the memory dies as close to the processor as possible. For example, while socketed memory in a desktop or server may be several centimeters from a processor, HBM modules are typically within a few millimeters of the processor, and greater distances can significantly worsen performance. These limitations can negatively impact both the capacity of HBM and the available bandwidth.

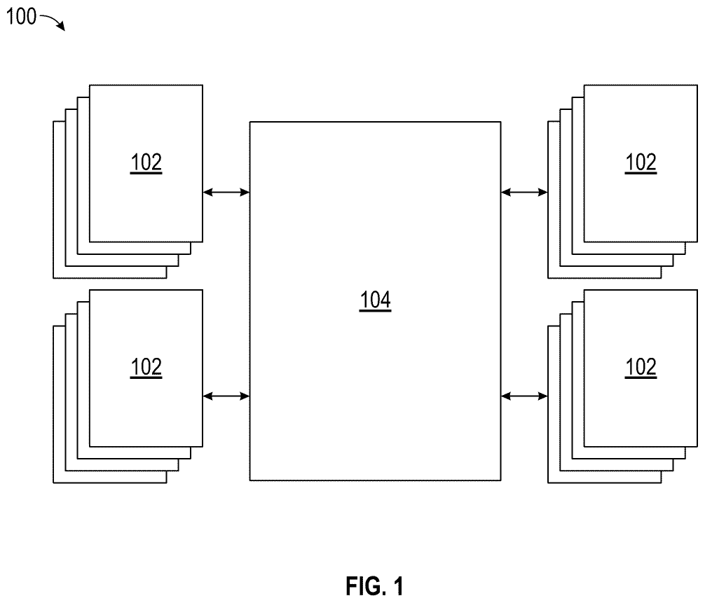

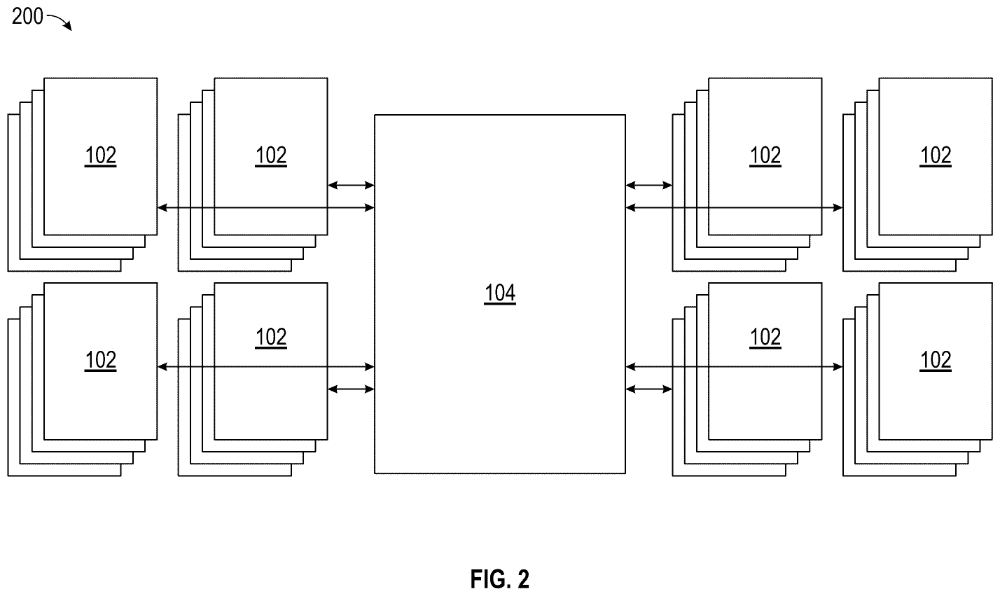

FIG. 1 illustrates a conventional HBM 100 approach in which stacked memory modules 102 (e.g., four stacked memory modules) are arranged around a processor 104 (e.g., a CPU or GPU). FIG. 2 illustrates another HBM 200 implementation that uses an approach similar to that shown in FIG. 1. However, the implementation shown in FIG. 2 has significant drawbacks. While the number of memory modules 102 (i.e., memory stacks) is doubled from FIG. 1 to FIG. 2, the additional memory modules 102 are located a greater distance from the processor 104, negatively impacting performance. Thus, there is a need for approaches that can increase memory capacity while maintaining or even increasing performance.

Some embodiments herein can significantly improve the bandwidth, capacity, or both of HBM. Advantageously, some embodiments herein can improve bandwidth, capacity, or both without requiring larger areas, significantly increasing the distance between the processor and memory dies, and/or having a significant impact on power consumption.

One approach can be to vertically stack HBM memory units (e.g., stacks of four DRAM dies) on top of one other, for example as described in U.S. patent application Ser. No. 18/052,399, filed Nov. 3, 2022, the entire contents of which are incorporated by reference herein in their entirety and for all purposes. Two or more memory units can be stacked on top of one another to form a memory module. To accommodate the large number of input/output connections to support multiple memory units in a single memory module, it can be important to have small contacts and small pitches. Accordingly, rather than forming connections using relatively large metal bumps as can be done in conventional approaches, direct hybrid bonding, as described in more detail herein, can be used to bond and form electrical connections between the components of the memory module.

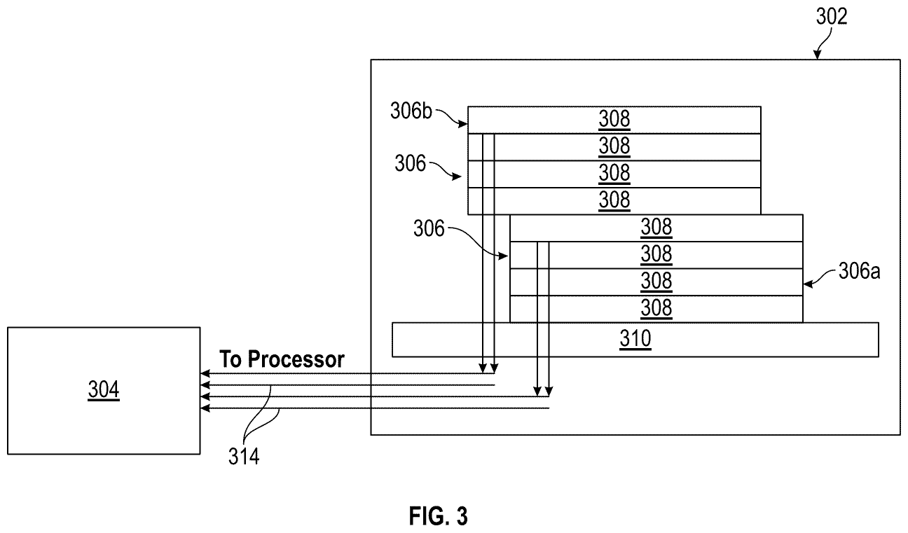

FIG. 3 shows an example embodiment of a memory module 302 (e.g., an HBM module) having two memory units 306, each memory unit 306a, 306b comprising a plurality of (e.g., four) memory dies (e.g., DRAM dies) 308 hybrid bonded to and stacked on one another. As shown in FIG. 3, the memory units 306 can be stacked on top of one another and can be stacked on a logic layer 310. The memory module 302 can be electrically connected to a processor 304 (e.g., a CPU or GPU). This design can offer increased density and bandwidth, but the design may utilize modifications to the processor 304 as the number of input/output connections has been doubled (and could be tripled, quadrupled, etc., depending upon how many memory units are stacked together to form the memory module).

In some embodiments, it can be preferable to increase memory capacity without requiring an increase in the number of input/output connections to the processor. This can simplify interconnections and reduce or eliminate the need to modify a processor design to accommodate memory modules that have different input/output connections than more conventional HBM modules. Accordingly, some implementations can use a serializer-deserializer (SerDes) in place between the processor 304 and the memory 306. In some embodiments, the SerDes can be built into a multichannel memory module, although not all implementations may include the SerDes as part of the memory module. To a processor 304, the multichannel memory module 302 appears and behaves as a conventional HBM module design with a single channel.

Such an approach offers several advantages. In addition to presenting itself as a single module, the memory module 302 can be configured to take advantage of multiple internal channels to improve performance. For example, in a memory module 302 with two memory units 306, there can be two internal channels 314, one connected to the first memory unit 306a and the other connected to the second memory unit 306b. In some embodiments, the module can be configured to write and/or read from both memory units simultaneously. Thus, in the case of two memory units 306, the internal bandwidth of the module can be increased significantly, for example approximately doubled.

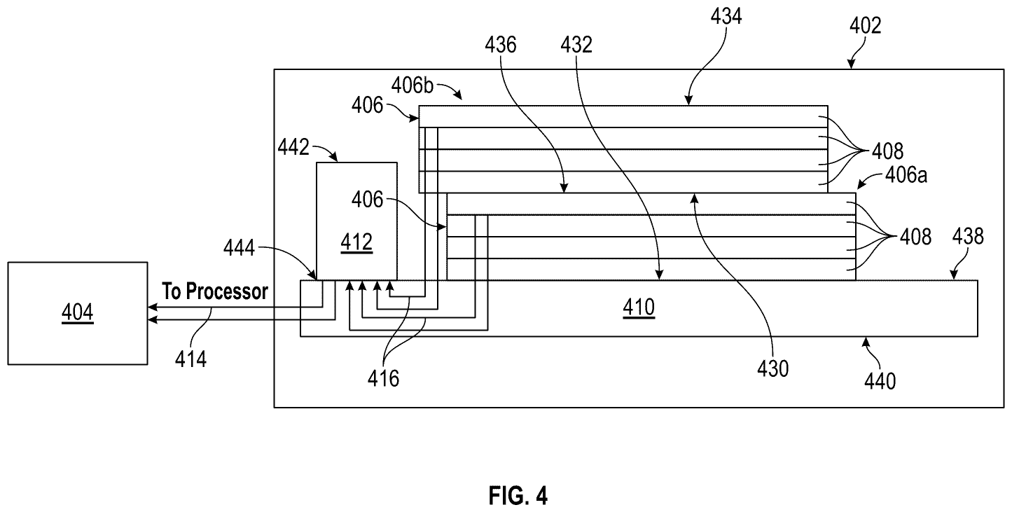

FIG. 4 illustrates an example multichannel memory module 402 according to some embodiments. In FIG. 4, the memory module 402 comprises two memory units 406 (e.g., first memory unit 406a and second memory unit 406b), each comprising four memory dies (e.g., DRAM dies) 408 hybrid bonded to one another. The memory dies 408 can also be stacked on one another. The first memory unit 406a can include a top surface 430 and a bottom surface 432 opposite the top surface 430. The second memory unit 406b can include a top surface 434 and a bottom surface 436 opposite the top surface 434. The memory units 406 can be vertically stacked on top of a logic die 410 (e.g., a memory controller configured to manage the flow of data to and from the memory units). The logic die 410 can include a top surface 438 and a bottom surface 440. In some embodiments, the bottom surface 436 of the second memory unit 406b can disposed on the top surface 430 of the first memory unit 406a. Furthermore, the bottom surface 432 of the first memory unit 406a can disposed on the top surface 438 of the logic die 410.

A SerDes 412 can be included in the memory module 402 in an electrical path between the memory units 406 and the processor 404. The SerDes 412 can receive signals (e.g., data) that originates from both memory units 406 and can combine the data into a single stream before sending it to the processor 404. In some embodiments, the SerDes 412 can receive a single stream from a processor 404 and a memory controller 410 (e.g., the logic shown in FIG. 4) can be configured to split the data across the memory units 406. The SerDes 412 can include a top surface 442 and a bottom surface 444 opposite the top surface 442. In some embodiments, the bottom surface 444 of the SerDes 412 can disposed on the top surface 438 of the logic die 410.

Due to the large number of interconnects present in a memory module 402 such as the one shown in FIG. 4, it can be important to have small feature sizes (e.g., small contact pads and small pitches). For example, in the configuration shown in FIG. 4, there can be one externally connected channel 414 (e.g., to connect to a processor) and two internal channels 416 (e.g., one channel for each memory unit). As more memory units are added, the number of interconnects can increase significantly. For example, there can be two internal channels for each external channel or another ratio, such as 4:1, 8:1, 16:1, 32:1, and so forth. In general, the number of internal channels can be greater than the number of external channels. In some embodiments, direct hybrid bonding can be used to bond the components of the memory module 402 (e.g., to bond the DRAM dies 408 to each other, to bond the memory units 406 to each other, to bond memory units 406 to the logic die 410, to bond the SerDes 412 to the logic die 410, and so forth).

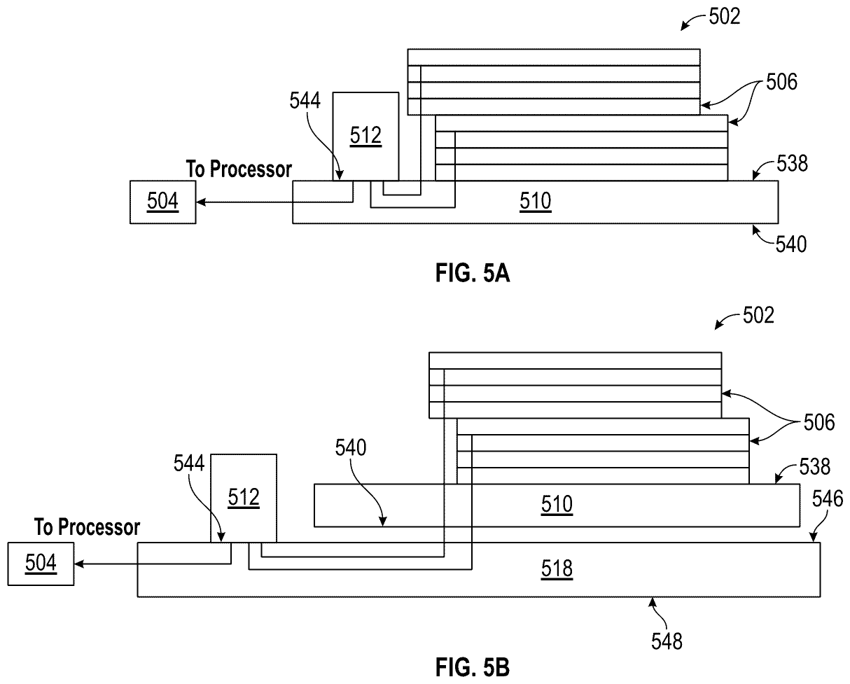

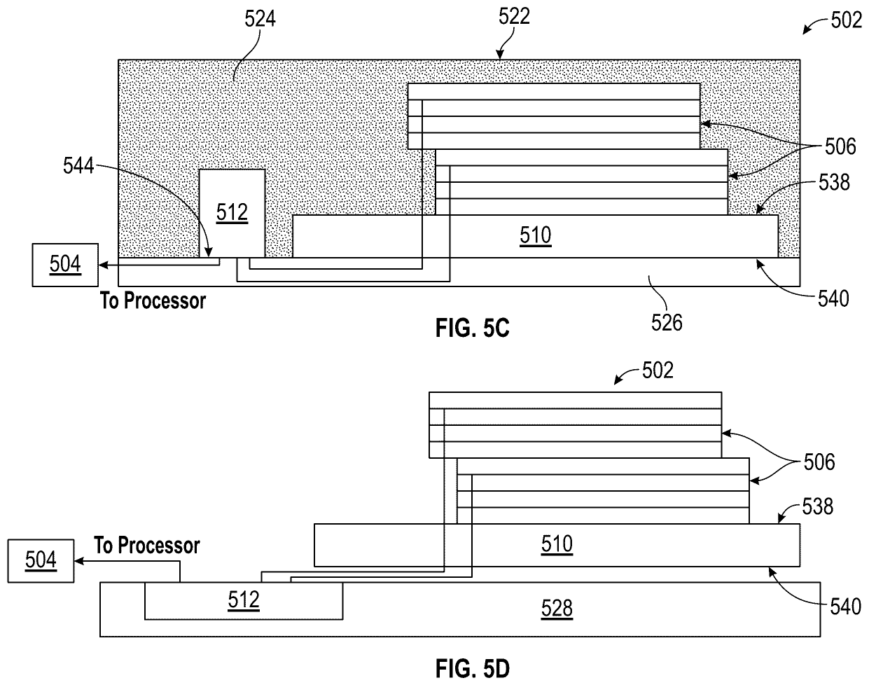

Various approaches can be used to implement multichannel memory. FIGS. 5A-5D illustrate example implementations of multichannel memory using a SerDes 512. In FIG. 5A, memory units 506 are stacked on top of a logic die 510. A SerDes 512 is attached (e.g., directly hybrid bonded) to the logic die 510, and signals between the processor 504 and memory units 506 pass through the SerDes 512. In FIG. 5B, a memory module 502 can include memory units 506 and a logic unit 510, and a SerDes 512 can be disposed on an interposer 518 outside of a memory module package 520. The interposer 518 can include a top surface 546 and a bottom surface 548 opposite the top surface 546. The interposer 518 can comprise any suitable type of interposer, such as a semiconductor or dielectric substrate, an integrated device die or wafer, a reconstituted element (e.g., one or more encapsulated dies with routing and bonding layer(s) formed thereon), a package substrate with a direct bonding layer thereon, etc. The memory module 502 can be bonded (e.g., directly hybrid bonded) to the interposer 518. A bottom surface 540 of the logic die 510 can be disposed on a top surface 546 of the interposer. Additionally, a bottom surface 544 of the serializer-deserializer 512 can be disposed on the top surface 548 of the interposer. As in FIGS. 5A-5B, signals between a processor 504 and the memory units 506 can pass through the SerDes 512.

FIG. 5C illustrates an example of a fanout package according to some embodiments. Unless otherwise noted, the components of FIG. 5C can be the same as or generally similar to like-numbered components of FIGS. 5A-5C and can be assembled and/or can operate in a generally similar manner. A fanout package can enable the connection of memory units to external interfaces, such as processors. The fanout configuration can be designed to optimize the transmission of data between the memory units and the external memory controller or host system. In FIG. 5C, a memory stack 522 (i.e., memory module) can include memory units 506 and a logic die 510. The memory stack 522 can be embedded in an encapsulant 524. A SerDes 512 can also be embedded in the encapsulant 524. In various embodiments, the encapsulant 524 can comprise one or multiple dielectric layers, e.g., one or multiple inorganic dielectric layers (such as silicon oxide, silicon nitride, silicon oxynitrocarbide, etc.). In some embodiments, the encapsulant 524 can comprise an organic insulating material such as a molding compound or epoxy. A redistribution layer 526 can be formed (e.g., deposited) over an exposed surface of the SerDes 512 and the logic die 510, providing electrical connections between the SerDes 512 and logic die 510 as well as external connections for interfacing with a processor 504. In some embodiments, the redistribution layer 526 can be deposited or directly hybrid bonded (e.g., by way of a transfer bonding process). In FIG. 5D, a SerDes 512 can be embedded into a substrate 528 (e.g., a printed circuit board). The substrate 528 can comprise an organic, ceramic or inorganic substrate, with a cavity in which the SerDes element 512 can be disposed. A memory module 502, which can include a logic die 510 and memory units 506, can be electrically connected to the SerDes 512, which can be connected to the processor 504.

As mentioned above, the use a serializer-deserializer (SerDes) in place between any of the processors and the memories described herein can improve performance of the multichannel memory module since the multichannel memory module can appear and behave as a conventional HBM module design with a single channel. The memory module can be configured to take advantage of multiple internal channels to improve performance. The memory module can write and/or read from two or more memory units simultaneously, thus increasing the internal bandwidth of the memory module.

### Direct Bonding

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 608a and/or 608b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10%larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

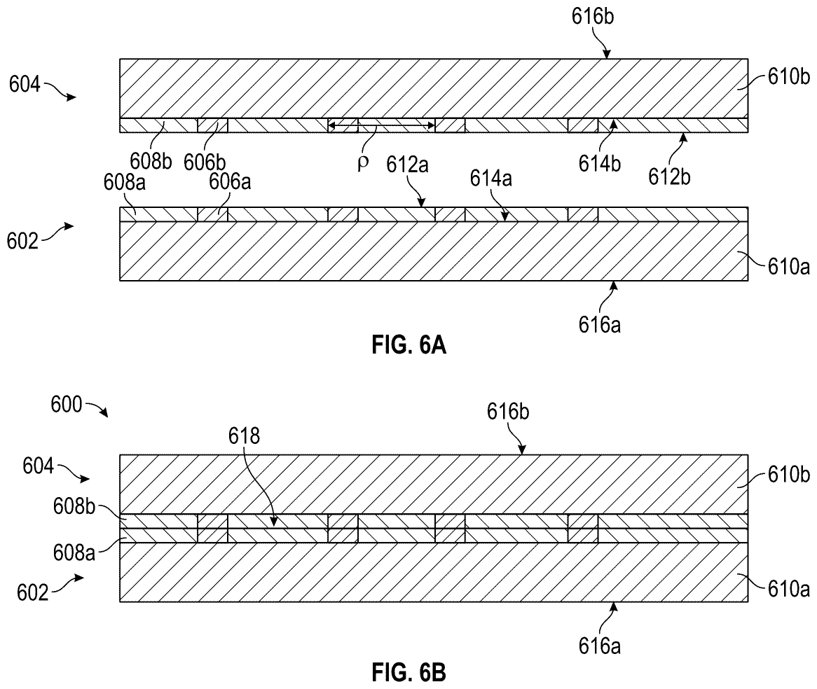

FIGS. 6A and 6B schematically illustrate cross-sectional side views of first and second elements 602, 604 prior to and after, respectively, a process for forming a directly bonded structure, and more particularly a hybrid bonded structure, according to some embodiments. In FIG. 6B, a bonded structure 600 comprises the first and second elements 602 and 604 that are directly bonded to one another at a bond interface 618 without an intervening adhesive. Conductive features 606a of a first element 602 may be electrically connected to corresponding conductive features 606b of a second element 604. In the illustrated hybrid bonded structure 600, the conductive features 606a are directly bonded to the corresponding conductive features 606b without intervening solder or conductive adhesive.

The conductive features 606a and 606b of the illustrated embodiment are embedded in, and can be considered part of, a first bonding layer 608a of the first element 602 and a second bonding layer 608b of the second element 604, respectively. Field regions of the bonding layers 608a, 608b extend between and partially or fully surround the conductive features 606a, 606b. The bonding layers 608a, 608b can comprise layers of non-conductive materials suitable for direct bonding, as described above, and the field regions are directly bonded to one another without an adhesive. The non-conductive bonding layers 608a, 608b can be disposed on respective front sides 614a, 614b of base substrate portions 610a, 610b.

The first and second elements 602, 604 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 602, 604, and back-end-of-line (BEOL) interconnect layers over such semiconductor portions. The bonding layers 608a, 608b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 610a, 610b, and can electrically communicate with at least some of the conductive features 606a, 606b. Active devices and/or circuitry can be disposed at or near the front sides 614a, 614b of the base substrate portions 610a, 610b, and/or at or near opposite backsides 616a, 616b of the base substrate portions 610a, 610b. In other embodiments, the base substrate portions 610a, 610b may not include active circuitry, but may instead comprise dummy substrates, passive interposers, passive optical elements (e.g., glass substrates, gratings, lenses), etc. The bonding layers 608a, 608b are shown as being provided on the front sides of the elements, but similar bonding layers can be additionally or alternatively provided on the back sides of the elements.

In some embodiments, the base substrate portions 610a, 610b can have significantly different coefficients of thermal expansion (CTEs), and bonding elements that include such different based substrate portions can form a heterogenous bonded structure. The CTE difference between the base substrate portions 610a and 610b, and particularly between bulk semiconductor (typically single crystal) portions of the base substrate portions 610a, 610b, can be greater than 5 ppm/° C. or greater than 10 ppm/° C. For example, the CTE difference between the base substrate portions 610a and 610b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 610a, 610b can comprise optoelectronic single crystal materials, including perovskite materials, that are useful for optical piezoelectric or pyroelectric applications, and the other of the base substrate portions 610a, 610b comprises a more conventional substrate material. For example, one of the base substrate portions 610a, 610b comprises lithium tantalate (LiTaO3) or lithium niobate (LiNbO3), and the other one of the base substrate portions 610a, 610b comprises silicon (Si), quartz, fused silica glass, sapphire, or a glass. In other embodiments, one of the base substrate portions 610a, 610b comprises a III-V single semiconductor material, such as gallium arsenide (GaAs) or gallium nitride (GaN), and the other one of the base substrate portions 610a, 610bcan comprise a non-III-V semiconductor material, such as silicon (Si), or can comprise other materials with similar CTE, such as quartz, fused silica glass, sapphire, or a glass. In still other embodiments, one of the base substrate portions 610a, 610b comprises a semiconductor material and the other of the base substrate portions 610a, 610b comprises a packaging material, such as a glass, organic or ceramic substrate.

In some arrangements, the first element 602 can comprise a singulated element, such as a singulated integrated device die. In other arrangements, the first element 602 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 604 can comprise a singulated element, such as a singulated integrated device die. In other arrangements, the second element 604 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive and may include markings indicative of the common singulation process for the bonded structure (e.g., saw markings if a saw singulation process is used).

While only two elements 602, 604 are shown, any suitable number of elements can be stacked in the bonded structure 600. For example, a third element (not shown) can be stacked on the second element 604, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 602. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 608a, 608b, the bonding layers 608a, 608b can be prepared for direct bonding. Non-conductive bonding surfaces 612a, 612b at the upper or exterior surfaces of the bonding layers 608a, 608b can be prepared for direct bonding by polishing, for example, by chemical mechanical polishing (CMP). The roughness of the polished bonding surfaces 612a, 612b can be less than 30 Å rms. For example, the roughness of the bonding surfaces 612a and 612b can be in a range of about 0.1 Å rms to 15 Å rms, 0.5 Å rms to 10 Å rms, or 1 Å rms to 5 Å rms. Polishing can also be tuned to leave the conductive features 606a, 606b recessed relative to the field regions of the bonding layers 608a, 608b.

Preparation for direct bonding can also include cleaning and exposing one or both of the bonding surfaces 612a, 612b to a plasma and/or etchants to activate at least one of the surfaces 612a, 612b. In some embodiments, one or both of the surfaces 612a, 612b can be terminated with a species after activation or during activation (e.g., during the plasma and/or etch processes). Without being limited by theory, in some embodiments, the activation process can be performed to break chemical bonds at the bonding surface(s) 612a, 612b, and the termination process can provide additional chemical species at the bonding surface(s) 612a, 612b that alters the chemical bond and/or improves the bonding energy during direct bonding. In some embodiments, the activation and termination are provided in the same step, e.g., a plasma to activate and terminate the surface(s) 612a, 612b. In other embodiments, one or both of the bonding surfaces 612a, 612b can be terminated in a separate treatment to provide the additional species for direct bonding. In various embodiments, the terminating species can comprise nitrogen. For example, in some embodiments, the bonding surface(s) 612a, 612b can be exposed to a nitrogen-containing plasma. Other terminating species can be suitable for improving bonding energy, depending upon the materials of the bonding surfaces 612a, 612b. Further, in some embodiments, the bonding surface(s) 612a, 612b can be exposed to fluorine. For example, there may be one or multiple fluorine concentration peaks at or near a bond interface 618 between the first and second elements 602, 604. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 600, the bond interface 618 between two non-conductive materials (e.g., the bonding layers 608a, 608b) can comprise a very smooth interface with higher nitrogen (or other terminating species) content and/or fluorine concentration peaks at the bond interface 618. In some embodiments, the nitrogen and/or fluorine concentration peaks may be detected using various types of inspection techniques, such as SIMS techniques. The polished bonding surfaces 612a and 612b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 608a and 608b can be directly bonded to one another without an adhesive. In some embodiments, the elements 602, 604 are brought together at room temperature, without the need for application of a voltage, and without the need for application of external pressure or force beyond that used to initiate contact between the two elements 602, 604. Contact alone can cause direct bonding between the non-conductive surfaces of the bonding layers 608a, 608b (e.g., covalent dielectric bonding). Subsequent annealing of the bonded structure 600 can cause the conductive features 606a, 606b to directly bond.

In some embodiments, prior to direct bonding, the conductive features 606a, 606b are recessed relative to the surrounding field regions, such that a total gap between opposing contacts after dielectric bonding and prior to anneal is less than 15 nm, or less than 10 nm. Because the recess depths for the conductive features 606a and 606b can vary across each element, due to process variation, the noted gap can represent a maximum or an average gap between corresponding conductive features 606a, 606b of two joined elements (prior to anneal). Upon annealing, the conductive features 606a and 606b can expand and contact one another to form a metal-to-metal direct bond.

During annealing, the conductive features 606a, 606b (e.g., metallic material) can expand while the direct bonds between surrounding non-conductive materials of the bonding layers 608a, 608b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 606a, 606b can comprise discrete pads, contacts, electrodes, or traces at least partially embedded in the non-conductive field regions of the bonding layers 608a, 608b. In some embodiments, the conductive features 606a, 606b can comprise exposed contact surfaces of TSVs (e.g., through silicon vias).

As noted above, in some embodiments, in the elements 602, 604 of FIG. 6A prior to direct bonding, portions of the respective conductive features 606a and 606b can be recessed below the non-conductive bonding surfaces 612a and 612b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 606a, 606b or to average depths of the recesses relative to local non-conductive field regions. Even for an individual conductive feature 606a, 606b, the vertical recess can vary across the feature, and so can be measured at or near the lateral middle or center of the cavity in which a given conductive feature 606a, 606b is formed, or can be measured at the sides of the cavity.

Beneficially, the use of hybrid bonding techniques (such as Direct Bond Interconnect, or DBIR, techniques commercially available from Adeia of San Jose, CA) can enable high density of connections between conductive features 606a, 606b across the direct bond interface 618 (e.g., small or fine pitches for regular arrays).

In some embodiments, a pitch p of the conductive features 606a, 606b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 606a and 606b to one of the lateral dimensions (e.g., a diameter) of the bonding pad is less than 20, or less than 10, or less than 5, or less than 3 and sometimes desirably less than 2. In various embodiments, the conductive features 606a and 606b and/or traces can comprise copper or copper alloys, although other metals may be suitable, such as nickel, aluminum, or alloys thereof. The conductive features disclosed herein, such as the conductive features 606a and 606b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 602, 604, as shown, the orientations of one or more conductive features 606a, 606b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 606b in the bonding layer 608b (and/or at least one internal conductive feature, such as a BEOL feature) of the upper element 604 may be tapered or narrowed upwardly, away from the bonding surface 612b. By way of contrast, at least one conductive feature 606a in the bonding layer 608a (and/or at least one internal conductive feature, such as a BEOL feature) of the lower element 602 may be tapered or narrowed downwardly, away from the bonding surface 612a. Similarly, any bonding layers (not shown) on the backsides 616a, 616b of the elements 602, 604 may taper or narrow away from the backsides, with an opposite taper orientation relative to front side conductive features 606a, 606b of the same element.

As described above, in an anneal phase of hybrid bonding, the conductive features 606a, 606b can expand and contact one another to form a metal-to-metal direct bond. In some embodiments, the materials of the conductive features 606a, 606b of opposite elements 602, 604 can interdiffuse during the annealing process. In some embodiments, metal grains grow into each other across the bond interface 618. In some embodiments, the metal is or includes copper, which can have grains oriented along the 111 crystal plane for improved copper diffusion across the bond interface 618. In some embodiments, the conductive features 606a and 606b may include nanotwinned copper grain structure, which can aid in merging the conductive features during anneal. There is substantially no gap between the non-conductive bonding layers 608a and 608b at or near the bonded conductive features 606a and 606b. In some embodiments, a barrier layer may be provided under and/or laterally surrounding the conductive features 606a and 606b (e.g., which may include copper). In other embodiments, however, there may be no barrier layer under the conductive features 606a and 606b.

In the foregoing specification, the systems and processes have been described with reference to specific embodiments thereof. It will, however, be evident that various modifications and changes may be made thereto without departing from the broader spirit and scope of the embodiments disclosed herein. The specification and drawings are, accordingly, to be regarded in an illustrative rather than restrictive sense.

Indeed, although the systems and processes have been disclosed in the context of certain embodiments and examples, it will be understood by those skilled in the art that the various embodiments of the systems and processes extend beyond the specifically disclosed embodiments to other alternative embodiments and/or uses of the systems and processes and obvious modifications and equivalents thereof. In addition, while several variations of the embodiments of the systems and processes have been shown and described in detail, other modifications, which are within the scope of this disclosure, will be readily apparent to those of skill in the art based upon this disclosure. It is also contemplated that various combinations or sub-combinations of the specific features and embodiments of the embodiments may be made and still fall within the scope of the disclosure. It should be understood that various features and embodiments of the disclosed embodiments can be combined with, or substituted for, one another in order to form varying modes of the embodiments of the disclosed systems and processes. Any methods disclosed herein need not be performed in the order recited. Thus, it is intended that the scope of the systems and processes herein disclosed should not be limited by the particular embodiments described above.

It will be appreciated that the systems and methods of the disclosure each have several innovative embodiments, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

It will also be appreciated that conditional language used herein, such as, among others, “can,” “could,” “might,” “may,” “for example,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one or more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the embodiments are not to be limited to the particular forms or methods disclosed, but, to the contrary, the embodiments are to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (for example, as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (for example, as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

1-59. (canceled)

60. A bonded structure comprising:
a carrier;
a first memory unit disposed on the carrier, the first memory unit comprising a first memory channel, the first memory unit comprising a first plurality of memory dies directly hybrid bonded to one another;
a second memory unit comprising a second memory channel different from the first memory channel, the second memory unit comprising a second plurality of memory dies directly hybrid bonded to one another, the second memory unit stacked on top of the first memory unit; and
a serializer-deserializer disposed in or on the carrier and electrically connected to the first and second memory channels of the first and second memory units, the serializer-deserializer having an external channel configured to electrically connect the bonded structure to a processor.

61. The bonded structure of claim 60, wherein the carrier comprises a logic die.

62. The bonded structure of claim 60, further comprising a logic die;
wherein the carrier comprises an interposer; and
wherein the logic die is disposed between the first memory unit and the interposer.

63. The bonded structure of claim 60, further comprising:
an encapsulant; and
a logic die;
wherein the carrier comprises a redistribution layer;
wherein the logic die is disposed between the first memory unit and the redistribution layer; and
wherein the first memory unit, the second memory unit, the logic die, and the serializer-deserializer are partially enclosed in the encapsulant.

64. The bonded structure of claim 60, further comprising a logic die,
wherein the carrier comprises a printed circuit board; and
wherein the logic die is disposed between the first memory unit and the printed circuit board.

65. The bonded structure of claim 60, wherein the first memory unit is directly hybrid bonded to the second memory unit.

66. The bonded structure of claim 60, wherein the first memory unit is directly hybrid bonded to the carrier.

67. The bonded structure of claim 60, wherein the serializer-deserializer is directly hybrid bonded to the carrier.

68. A bonded structure comprising:
a carrier;
a first memory unit disposed on the carrier, the first memory unit comprising a first memory channel and a first plurality of memory dies directly hybrid bonded to one another;
a second memory unit comprising a second memory channel different from the first memory channel and a second plurality of memory dies directly hybrid bonded to one another, the second memory unit stacked on top of the first memory unit; and
a serializer-deserializer directly hybrid bonded to the carrier and electrically connected to the first and second memory channels of the first and second memory units, the serializer-deserializer having an external channel configured to electrically connect the bonded structure to a processor.

69. The bonded structure of claim 68, wherein the bonded structure has a first number of internal channels electrically connecting the serializer-deserializer, the carrier, the first memory unit, and the second memory unit, wherein a second number of external channels is configured to electrically connect the structure to a processor, and wherein the first number is different than the second number.

70. The bonded structure of claim 68, further comprising:
a logic die;
wherein the carrier comprises an interposer; and
wherein the logic die is disposed between the first memory unit and the interposer.

71. The bonded structure of claim 68, further comprising:
an encapsulant; and
a logic die;
wherein the carrier comprises a redistribution layer;
wherein the logic die is disposed between the first memory unit and the redistribution layer; and
wherein the first memory unit, the second memory unit, the logic die, and the serializer-deserializer are partially enclosed in the encapsulant.

72. The bonded structure of claim 68, wherein the first memory unit is directly hybrid bonded to the second memory unit.

73. The bonded structure of claim 68, wherein the first memory unit is directly hybrid bonded to the carrier.

74. A bonded structure comprising:
a carrier;
a first memory unit comprising a first memory channel and a second memory unit comprising a second memory channel different from the first memory channel, wherein the second memory unit is stacked on top of the first memory unit, wherein the first memory unit and the second memory unit are disposed on the carrier, wherein the first memory unit comprises a first plurality of memory dies directly hybrid bonded to one another, wherein the second memory unit comprises a second plurality of memory dies directly hybrid bonded to one another; and
a serializer-deserializer is disposed on or at least partially embedded in the carrier and electrically connected to the first and second memory channels of the first and second memory units, the serializer-deserializer having an external channel configured to electrically connect the bonded structure to a processor.

75. The bonded structure of claim 73, wherein the bonded structure has a first number of internal channels electrically connecting the serializer-deserializer, the carrier, the first memory unit, and the second memory unit, wherein a second number of external channels is configured to electrically connect the structure to a processor, and wherein the first number is different than the second number.

76. The bonded structure of claim 73, wherein the serializer-deserializer is directly hybrid bonded to the carrier.

77. The bonded structure of claim 73, wherein the carrier comprises a logic die.

78. The bonded structure of claim 73, further comprising:
a logic die;
wherein the carrier comprises an interposer, and
wherein the logic die is disposed between the first memory unit and the interposer.

79. The bonded structure of claim 73, further comprising:
a logic die;
wherein the carrier comprises a printed circuit board; and
wherein the logic die is disposed between the first memory unit and the printed circuit board.
